(19) United States
(12) Patent Application Publication
(10) Pub. No.: US 2018/0072916 A1
(43) Pub. Date: Mar. 15, 2018

(54) DIAMOND-BASED SLURRIES WITH IMPROVED SAPPHIRE REMOVAL RATE AND SURFACE ROUGHNESS

(71) Applicant: Cabot Microelectronics Corporation, Aurora, IL (US)

(72) Inventors: Prativa PANDEY, Aurora, IL (US); Brian REISS, Woodridge, IL (US); Michael WHITE, Ridgefield, CT (US)

(21) Appl. No.: 15/564,605

(22) PCT Filed: Apr. 13, 2016
(86) PCT No.: PCT/US2016/027189

§ 371 Date: Oct. 5, 2017

Related U.S. Application Data
(60) Provisional application No. 62/146,713, filed on Apr. 13, 2015.

(51) Int. Cl. C09G 1/02; H01L 21/306; H01L 21/321; H01L 21/768; C09G 1/04; C09G 1/06; C09K 3/14; C09K 13/06

(52) U.S. Cl. CPC C09G 1/02; H01L 21/30625; H01L 21/3212; H01L 21/76898; C09K 13/06; C09G 1/06; C09K 3/1409; C09K 3/1463; C09G 1/04

(57) ABSTRACT

The invention provides a chemical-mechanical polishing composition and a method of chemically-mechanically polishing a sapphire substrate. The composition contains a diamond abrasive and a pH adjuster. The method involves contacting the substrate with a polishing pad and the chemical-mechanical polishing composition, moving the polishing pad and the polishing composition relative to the substrate, and abrading at least a portion of the substrate to polish the substrate.

### BACKGROUND OF THE INVENTION

Sapphire is the single-crystal form of aluminum oxide (Al₂O₃) possessing excellent optical, mechanical, and chemical properties. For example, sapphire retains its high strength at high temperatures, has good thermal properties, excellent transparency, excellent chemical stability, possesses chip resistance, durability, scratch resistance, radiation resistance, and flexural strength at elevated temperatures.

Sapphire is increasingly becoming the material of choice for engineers faced with design challenges in the semiconductor manufacturing industry. For example, the properties provided by sapphire make it suitable for use in plasma containment tubes, process gas injectors, thermocouple protection assemblies, viewports and sight windows, end effectors, gas diffusion plates, substrates, and wafers.

Sapphire wafers are commonly cut along a number of crystallographic axes, such as the C-plane (0001 orientation, also called the 0-degree plane or the basal plane), the A-plane (11-20 orientation, also referred to as 90 degree sapphire) and the R-plane (1-102 orientation, 57.6 degrees from the C-plane). R-plane sapphire, which is particularly preferred for silicon-on-sapphire materials used in semiconductor, microwave and pressure transducer application, is about 4 times more resistant to polishing than C-plane sapphire, which is typically used in optical systems, infrared detectors, and growth of gallium nitride for light-emitting diode applications.

While sapphire provides numerous advantages, due to sapphire's hardness and resistance to chemical attack, polishing and planarizing sapphire presents many difficulties. Hard abrasives having high removal rates are often required to provide acceptable polishing rates. However, these abrasives can scratch and damage the sapphire surface. While softer, slower acting abrasives can be used to reduce this potential for scratching and damage, the downside with such abrasives is the often unacceptable times required to achieve the desired level of surface polishing and planarization.

Given these and other deficiencies observed in the art, it would be highly desirable to develop improved abrasive slurry compositions that provide fast removal rate while still minimizing defects and scratching.

### DETAILED DESCRIPTION OF THE INVENTION

The invention provides a polishing composition and a method of polishing a substrate. The polishing composition provides diamond abrasive particles, preferably in the size range of about 2 μm to about 4 μm. The composition also comprises a medium in which the particles are suspended. The polishing composition also comprises acid or base additives to adjust the pH.

Embodiments of the invention provide a diamond based polishing composition that exhibits high removal rates and low surface roughness for sapphire substrates. In accordance with some embodiments, the diamond based polishing composition is used to polish a sapphire substrate in a chemical-mechanical polishing process.

The substrate to be polished using the polishing composition and method of the invention can be any suitable sapphire substrate. For example, the sapphire substrate may be a C-plane sapphire substrate, or an A-plane sapphire substrate. In some embodiments, A-plane sapphire substrates are preferred.

The polishing composition includes diamond abrasive particles. Any suitable diamond abrasive particle may be used. The diamond abrasive particles are preferably particles with a relatively large average particle size. The diamond abrasive may be irregularly shaped, or with a smooth surface. Preferably, the diamond abrasive is preferably irregularly shaped.

The diamond particles can have any suitable average particle size (i.e., average particle diameter). For clarity, it will be understood that, for non-spherical particles, the size of the particle is the diameter of the smallest sphere that encompasses the particle. For example, in some embodiments, the diamond has an average particle size of from about 2 μm to about 4 μm. In some embodiments, the diamond has an average particle size of, e.g., from about 1 μm to about 5 μm, from about 1 μm to about 4 μm, or from about 3 μm to about 5 μm. Preferably, the diamond particles can have an average particle size of at least about 1 μm.

The diamond particles can be present in any suitable amount. For example, the diamond particles can be present in an amount of from about 0.5 wt. % to about 2 wt. %. In some embodiments, the silica is present, e.g., in an amount from about 0.25 wt. % to about 5 wt. %, such as from about 0.5 wt. % to about 4 wt. %, such as from about 0.5 wt. % to about 3 wt. %, or from about 0.25 wt. % to about 2 wt. %. Preferably, the diamond particles are present in an amount of from about 0.5 wt. % to about 2 wt. %.

The polishing composition optionally may contain a second diamond abrasive of a smaller average particle size. For example, the polishing compositions of the present invention may comprise diamond particles having an average particle size of at least about 1 μm, and a second diamond particle with an average particle size of less than about 1 nm. For example, in some embodiments, the second diamond particle has an average particle size of from about 0.01 nm to about 1 nm. In some embodiments, the silica has an average particle size of, e.g., from about 0.1 nm to about 0.5 nm, from about 0.1 nm to about 1 nm, or from about 0.01 nm to about 0.5 nm.

The polishing composition comprises a pH adjusting component. The pH adjusting component may be an acid or a base. Any suitable pH adjusting component may be used. Preferably, an acid may be nitric acid, sulfuric acid, hydrochloric acid or phosphoric acid. When the pH adjusting component is a base, preferably the base is sodium, potassium, cesium or ammonium hydroxide.

In some embodiments, the polishing composition liquid medium comprises water or a water soluble organic solvent, such as a glycol. For example, the polishing composition may comprise distilled water, ethylene glycol, propylene glycol or mixtures thereof.

In some embodiments, the polishing composition may include a polishing additive. The polishing additive is a compound that complexes with aluminum ion. Without limitation, the polishing additive may be a quaternary ammonium polymer or copolymer, such as a copolymer of diallyl dimethyl ammonium chloride and acrylic acid (e.g. Merquat 280). Further, the polishing additive may be maltol.

The polishing composition optionally includes a surfactant, a polymer, a complexing agent, rheology modifiers, thickening agents and/or a chelating agent. In some embodiments, the polymer and surfactant are water or alcohol soluble, or water or alcohol dispersible. In some embodiments, the complexing agent and chelating agent are soluble or dispersible in any suitable liquid medium.

The polishing composition of the invention can have any suitable pH. In some embodiments, the polishing composition can desirably have a pH of from about 3 to about 11. Without wishing to be bound by theory, the polishing rate of the inventive compositions will increase as the pH is lowered from 11 to 3. In some embodiments, a higher polishing rate is desired. In other embodiments, a lower polishing rate is desired. Therefore, in some embodiments, the polishing composition exhibits a pH of from about 3 to about 11, about 3 to about 7, such as from about 3 to about 6, from about 3 to about 5, from about 3 to about 4, or from about 7 to about 11, or from about 7 to about 10.

If desired, to achieve such a pH level, a pH adjuster can be utilized. Any suitable pH adjuster can be included in the polishing composition. By way of example, the pH adjuster can be in the form of one or more of nitric acid, sulfuric acid, and phosphoric acid. The pH adjuster is included in an amount effective to achieve the desired pH level, such as in an amount of from about 0.0001 wt. % to about 20 wt. %, e.g., from about 0.001 wt. % to about 10 wt. %, from about 0.01 wt. % to about 5 wt. %, or from about 0.02 wt. % to about 3 wt. %.

Biocides as known in the art can be used in some embodiments. The biocide can be any suitable biocide and can be present in the polishing composition in any suitable amount. By way of example, and not limitation, a suitable biocide is an isothuazolinone biocide, isothiazolinone, or the like. The amount of biocide used in the polishing composition typically can be from about 1 to about 60, e.g., about 1 to about 50 ppm, such as about 10 to about 20 ppm.

The polishing composition can be prepared by any suitable technique, many of which are known to those skilled in the art. The polishing composition can be prepared in a batch or continuous process. Generally, the polishing composition can be prepared by combining the components thereof in any order.

It will be understood that, generally, the actual quantity of one or more ingredient in compositions in accordance with embodiments of the invention (e.g., diamond abrasives, polishing additives; and water) may vary depending on the desired degree of dilution or concentration. In this respect, some embodiments can be packaged in the form of a concentrate (e.g., a 50 times concentrate, a 100 times concentrate, a 200 times concentrate, etc.) where water can be later added to dilute the solution, such as at a point of use (e.g., by an end user), or the solution can be packaged in a diluted form with water already included. For example, in some embodiments, the concentrated forms of each ingredient and/or the solution as a whole can facilitate ease of shipping, distribution, and sale. However in other embodiments, each ingredient and/or the solution as a whole can be in a diluted form, e.g., to simplify end use. Thus, the weight ranges for ingredients as set forth herein can refer to either the diluted or concentrated ranges.

Accordingly, each ingredient can be present in a diluted form that is suitable for end use or in a form that is concentrated and then diluted (e.g., 2 times, 5 times, 10 times, 25 times, 40 times, 50 times, 60 times, 70 times, 100 times, 125 times, 150 times, 175 times, 200 times, etc. to the diluted form). When the concentrate is diluted with an equal weight of water (e.g., 1 equal weight water, 4 equal weight of water, 9 equal weight of water, 24 equal weight of water, 39 equal weight of water, 49 equal weight of water, 59 equal weight water, 69 equal weight of water, 99 equal weight of water, 124 equal weight of water, respectively), each ingredient will be present in embodiments of the invention in an amount within the diluted ranges set forth below for each component. Furthermore, as will be understood by those of ordinary skill in the art, the concentrate can contain an appropriate fraction of the water present in the final solution. For example, in some applications, e.g., polishing compositions, the concentrate can contain an appropriate fraction of the water present in the final polishing composition in order to ensure that the polishing composition components are at least partially or fully dissolved in the concentrate.

As another illustrative embodiment, the polishing composition comprises, consists of, or consists essentially of a diamond abrasive, a pH adjusting additive and water.

In another illustrative embodiment, the composition comprises, consists of, or consists essentially of a diamond abrasive, a pH additive and an organic solvent, such as a glycol.

In another illustrative embodiment, the composition comprises, consists of, or consists essentially of diamond abrasives, a pH additive, a polishing additive and water.

In another illustrative embodiment, the composition comprises, consists of, or consists essentially of diamond abrasives, a pH additive, a polishing additive and an organic solvent, such as a glycol.

It shall be noted that the embodiments described above are merely examples of combinations of the ingredients in accordance with the invention. Other exemplary combinations are apparent from the entirety of the description herein. It will also be understood by one of ordinary skill in the art that each of these embodiments may be used in various combinations with the other embodiments provided herein.

It will be further understood that embodiments “consisting essentially of” the recited ingredients or method steps means that the composition precludes the inclusion of any additional ingredient or method step that materially affects the inventive polishing composition or method (e.g., ingredients or method steps that alter the desired effects of the invention, particularly with regard to removal rate as discussed herein or increasing negative effects on polishing performance (e.g., particularly with respect to surface roughness or defectivity)). Compounds or method steps that do not affect the removal rate or polishing performance with respect to surface roughness or defectivity can be included in such embodiments “consisting essentially of” the recited ingredients or method steps.

The invention also provides a method of polishing a sapphire substrate. The polishing method of the invention is particularly suited for use in conjunction with a chemical-mechanical polishing (CMP) apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the substrate, so as to abrade at least a portion of the substrate to polish the substrate.

A sapphire substrate can be planarized or polished with the chemical-mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

The method of polishing a substrate comprises, consists of, or consists essentially of (i) providing a substrate, (ii) providing a polishing pad, and (iii) providing a polishing composition as described herein in various embodiments. In the method, the polishing composition is dispensed to the surface of the substrate and the polishing pad contacts the surface of the substrate. The method also includes abrading at least a portion of the surface of the substrate to remove at least some portion of the substrate and to polish the surface of the substrate.

The following Examples further illustrate the invention but, of course, should not be construed as in any way limiting its scope.

### EXAMPLE 1

This Example demonstrates the effects of pH and diamond abrasive size in the slurry composition for polishing sapphire substrates.

All of the polishing data shown in Tables 1 and 2 were obtained on a Hyprez 15″ polishing tool using MH (Eminess Technologies, Scottsdale, Ariz.), IC1000™ (Dow Chemical Corporation, Midland, Mich.) or D100™ (Cabot Microelectronics Corporation, Aurora, Ill.) polishing pads at slurry flow rate of 30-60 mL/min and at 3-4 psi down force. Diamond abrasives were added at 0.5-2 wt. % solids in the formulations, suspended in either distilled water (DIW) or ethylene glycol. The diamond abrasives were either GMM (Item number 15231007, Sandvik Hyperion, New Jersey, USA) having a particle size of 0.1-0.5 nm, Hyperion (Sandvik Hyperion, New Jersey, USA) having a particle sizes of either 1-3 μm, 2-3 μm or 2-4 μm. The slurry compositions were adjusted to target pH values using either nitric acid or potassium hydroxide. The Sapphire substrates were 2 inch, A-plane wafers. The removal rate was measured by mass difference, by subtracting the final mass from the initial mass.

The data is shown in Tables 1 and 2 below. The data indicate that the larger diamond particle size gave increased removal rates for sapphire, when compared to the smaller GMM diamond particles. Additionally, the polishing rates increased as the pH value decreased from 11.

TABLE 1
Polishing data showing the effect of pH on sapphire removal rates
using GMM 0-0.5 nm diamond-based slurries

| | | | Medium for | Removal Rate |
|---|---|---|---|---|
| | Composition | pH | dispersion | (μm/h) |
| Slurry #1 | GMM 0-0.5 | 11 | DIW | 1.8 |
| | Diamond + Base | | | |
| Slurry #2 | GMM 0-0.5 | 9 | DIW | 1.8 |
| | Diamond + Base | | | |
| Slurry #3 | GMM 0-0.5 | 6 | DIW | 4.1 |
| | Diamond + Base | | | |
| Slurry #4 | GMM 0-0.5 | 5 | DIW | 4.3 |
| | Diamond + Base | | | |
| Slurry #5 | GMM 0-0.5 | 4.6 | DIW | 4.3-5.9 |
| | Diamond | | | |
| Slurry #6 | GMM 0-0.5 | 4 | DIW | 3.6 |
| | Diamond + acid | | | |
| Slurry #7 | GMM 0-0.5 | 3.5 | DIW | 3.5 |
| | Diamond + acid | | | |

TABLE 2
Polishing data showing the effect of pH on sapphire removal rates
using Hyperion 2-4 μm diamond-based slurries

| | | | Liquid | Removal Rate |
|---|---|---|---|---|
| | Composition | pH | Medium | (μm/h) |
| Slurry #1 | Hyperion 2-4 μm | 11 | Ethylene | 27.5 |
| | Diamond + Base | | glycol | |
| Slurry #2 | Hyperion 2-4 μm | 9 | Ethylene | 27.2 |
| | Diamond + Base | | glycol | |
| Slurry #3 | Hyperion 2-4 μm | 7.8 | Ethylene | 31.1 |
| | Diamond + Acid | | glycol | |
| Slurry #4 | Hyperion 2-4 μm | 7 | Ethylene | 40.6 |
| | Diamond + Acid | | glycol | |
| Slurry #5 | Hyperion 2-4 μm | 6 | Ethylene | 52.9 |
| | Diamond + Acid | | glycol | |
| Slurry #6 | Hyperion 2-4 μm | 5 | Ethylene | 50.9 |
| | Diamond + Acid | | glycol | |
| Slurry #7 | Hyperion 2-4 μm | 4.5 | Ethylene | 56.6 |
| | Diamond + Acid | | glycol | |

### EXAMPLE 2

This Example demonstrates the effect of diamond size and slurry chemistry on removal rates and surface roughness in sapphire polishing compositions.

The polishing conditions were identical to those described in Example 1. The sapphire substrate had a pre-polishing roughness of about 1500nm-1700 nm. Table 3 describes the compositions of the tested slurries. All of the slurries in Table 3 were prepared using either 1 wt. % or 2 wt. % (2×) diamond particles. The diamond particles were either the smaller GMM or larger Hyperion particles. The liquid medium was either, distilled water, ethylene glycol or propylene glycol. In slurries 6 and 7, the described amount of a copolymer of diallyl dimethyl ammonium chloride and acrylic acid (Merquat™ 280, Lubrizol) polishing additive was added at 1 wt. % or 0.02 wt. %, respectively. In slurry 8, the polishing additive was 1 wt. % maltol. Slurry 12 contained a polyurethane-based rheology modifier (Rheovis PU1191, BASF). The pH for the slurries was adjusted to 4.5+/−0.1 using either an acid or base, as described in Example 1. The removal rate was determined as described in Example 1. The surface roughness was determined using a Zygo New View™ (Zygo Corporation, Middlefield, Conn.) and analyzed using Metropro 8.1.5 software (Zygo Corporation, Middlefield, Conn.).

The results from Table 3 show that the inventive slurries show both a high polishing rate and a low surface roughness.

TABLE 3
Polishing data showing removal rates and surface roughness improvement of
different diamond based-slurries.

| | | | | Surface |
|---|---|---|---|---|
| | | Liquid | Removal Rate | Roughness. Ra |
| | Composition | Medium | (μm/h) | (Å) |
| Slurry #1 | GMM 0-0.5 | DIW or | 5.9 | 8-20 |
| | Diamond | Ethylene | | |
| | | glycol | | |
| Slurry #2 | Hyperion 2-4 μm | Ethylene | 34.5 | 18-20 |
| | Diamond (2X | glycol | | |
| | Solids) + Acid | | | |
| Slurry #3 | Hyperion 2-4 μm | Ethylene | 31.1 | 22-27 |
| | Diamond | glycol | | |
| Slurry #4 | GMM 0-0.5 | Ethylene | 25.4 | 6-12 |
| | Diamond + | glycol | | |
| | Hyperion 2-4 μm | | | |
| | Diamond + Acid | | | |
| Slurry #5 | Hyperion 2-4 μm | Ethylene | 52.9 | 9-20 |
| | Diamond + Acid | glycol | | |
| Slurry #6 | Hyperion 2-4 μm | Ethylene | 18.0 | 6-10 |
| | Diamond + 1 wt % | glycol | | |
| | Merquat 280 + Acid | | | |
| Slurry #7 | Hyperion 2-4 μm | Ethylene | 51.8 | — |
| | Diamond + 0.02 wt % | glycol | | |
| | Merquat 280 + Acid | | | |
| Slurry #8 | Hyperion 2-4 μm | Ethylene | 30 | 9-12 |
| | Diamond + 1 wt % | glycol | | |
| | maltol + Acid | | | |
| Slurry #9 | Hyperion 2-4 μm | Propylene | 12-17 | — |
| | Diamond + Acid | glycol (50-100% | | |
| | | in DIW) | | |
| Slurry #10 | Hyperion 2-4 μm | Ethylene | 26.2 | 10.6 |
| | Diamond + malic | glycol | | |
| | acid + Acid | | | |
| Slurry #11 | Hyperion 2-4 μm | Ethylene | 17.4 | 8.2 |
| | Diamond + Malic | glycol | | |
| | acid + Rheovis | | | |
| | PU1191 + Acid | | | |
| Slurry #12 | Hyperion 2-4 μm | Ethylene | 25 | <10 |
| | Diamond + 0.15 wt. | glycol (50-100% | | |
| | % Rheovis | in DIW) | | |
| | PU1191 + Acid | | | |
| Slurry #13 | Hyperion 2-3 μm | Ethylene | 24.4 | 7.9 |
| | Diamond + Acid | glycol | | |
| Slurry #14 | Hyperion 1-3 μm | Ethylene | 17.1 | 6.4 |
| | Diamond + Acid | glycol | | |
| Slurry #15 | Hyperion 1-3 μm + | Ethylene | 17.4 | 7.6 |
| | Hyperion 2-4 μm | glycol | | |
| | Diamond + Acid | | | |
| Slurry #16 | Hyperion 2-3 μm + | Ethylene | 24.1 | 8.0 |
| | Hyperion 2-4 μm | glycol | | |
| | Diamond + Acid | | | |
| Slurry #17 | Hyperion 1-3 μm + | Ethylene | 28.8 | 10.5 |
| | Hyperion 2-3 μm | glycol | | |
| | Diamond + Acid | | | |

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) diamond abrasive;
(b) pH adjusting compound;
(c) optionally, a polishing additive; and
(d) a liquid medium comprising water, a water soluble organic compound, or a combination thereof.

2. The composition of claim 1 wherein the diamond abrasive has an average size of at least 1 μm.

3. The composition of claim 1 wherein the diamond abrasive has an average size of about 2 μm to about 4 μm.

4. The composition of claim 1 wherein the pH adjusting compound is an acid. The composition of claim 1 wherein the pH adjusting compound is a base.

6. The composition of claim 1 wherein the liquid medium is a water soluble organic compound.

7. The composition of claim 1 wherein the liquid medium is a glycol.

8. The composition of claim 1 wherein the liquid medium is distilled water.

9. The composition of claim 1 wherein the polishing additive is present.

10. The composition of claim 9 wherein the polishing additive is selected from the group consisting of a surfactant, a polymer, a chelating agent or a complexing agent, and combinations thereof.

11. The composition of claim 9 wherein the polishing additive is a copolymer of diallyl dimethyl ammonium chloride and acrylic acid.

12. The composition of claim 9 wherein the polishing additive is maltol.

13. The composition of claim 1, further comprising a second diamond abrasive having a smaller average particle size from the diamond abrasive.

14. A chemical-mechanical polishing method for polishing a sapphire substrate which method comprises:
(i) contacting a sapphire substrate with a polishing pad and the polishing composition of claim 1:
(ii) moving the polishing pad and the polishing composition relative to the substrate to abrade at least a portion of the substrate to polish the substrate.
